(19) United States
(12) Patent Application Publication
(10) Pub. No.: US 2026/0047022 A1
(43) Pub. Date: Feb. 12, 2026

(54) OPTICAL FILM HAVING IMPROVED STIFFNESS AND DISPLAY DEVICE COMPRISING SAME

(71) Applicant: KOLON INDUSTRIES, INC., Seoul (KR)

(72) Inventors: Doo Li CHOI, Seoul (KR); Hyo Jun PARK, Seoul (KR); In Ho SHIN, Seoul (KR)

(21) Appl. No.: 19/105,099

(22) PCT Filed: Sep. 25, 2023
(86) PCT No.: PCT/KR2023/014632

§ 371 Date: Feb. 20, 2025

(30) Foreign Application Priority Data
Sep. 26, 2022 (KR) 10-2022-0121912

(51) Int. Cl. H05K 5/03

(52) U.S. Cl. CPC H05K 5/03

(57) ABSTRACT

An embodiment of the present invention provides an optical film which has a stiffness index (STI) of 80 to 190, based on a thickness of 50 μm. The Stiff Index is calculated by expression 1 below: [Expression 1] STI=Shore D hardness×tensile modulus. In expression 1, “STI” denotes a stiffness index, the Shore D hardness is a hardness measured using a Shore D durometer, and the tensile modulus is a tensile modulus measured using a universal testing machine.

### TECHNICAL FIELD

The present disclosure relates to an optical film with improved stiffness and a display device including the same.

### BACKGROUND ART

A polyimide (PI)-based resin is used as an automobile material, an aviation material, a spacecraft material, an insulating coating, an insulating film, a protective film or the like due to insolubility, chemical resistance, heat resistance, radiation resistance, superior mechanical strength, and the like thereof.

Recently, the use of an optical film as a cover window or a TFT substrate has been considered with the goal of reducing thickness and weight and increasing the flexibility of a display device. In order for the optical film to be usable as the cover window or TFT substrate, the optical film needs to have superior optical properties and excellent mechanical properties.

In particular, there is a need to develop optical films that can maintain excellent mechanical properties even when external force is applied thereto.

### DISCLOSURE

### Technical Problem

Therefore, the present disclosure has been made in view of the above problems, and it is one aspect of the present disclosure to provide an optical film with excellent Shore D hardness.

It is another aspect of the present disclosure to provide an optical film with excellent tensile modulus.

It is another aspect of the present disclosure to provide an optical film with excellent Stiff Index.

It is another aspect of the present disclosure to provide an optical film with excellent puncture strength.

### Technical Solution

In order to solve the problems described above, embodiments of the present disclosure may include the following configurations.

In accordance with one aspect of the present disclosure, provided is an optical film having a Stiff Index (STI) of 80 to 190, based on a thickness of 50 μm, wherein the Stiff Index is calculated by the following Equation 1:

$$STI = Shore D hardness \times tensile modulus \qquad [ Equation 1 ]$$

wherein STI represents a Stiff Index,
the Shore D hardness is measured using a Shore D hardness meter, and
the tensile modulus is measured using a universal testing machine.

The optical film may have a Shore D hardness of 15 to 19 HD, based on a thickness of 50 μm.

The optical film may have a tensile modulus of 5.0 to 10.0 GPa based on a thickness of 50 μm.

The optical film may have a puncture strength of 0.30 N/μm or more.

The optical film may include at least one of an imide repeating unit or an amide repeating unit.

The optical film may include the imide repeating unit and the amide repeating unit, wherein a ratio of the imide repeating unit to the amide repeating unit is 50:50 to 2:98, based on a total number of repeating units.

The optical film may include the imide repeating unit and the amide repeating unit, wherein a ratio of the imide repeating unit to the amide repeating unit is 10:90 to 2:98, based on the total number of repeating units.

The optical film may be produced from a polymerizable composition containing a diamine monomer and at least one of a dianhydride compound or a dicarbonyl compound.

The diamine monomer may include bis(trifluoromethyl)benzidine (TFDB).

The diamine monomer may further include bis(3-aminophenyl)sulfone (3DDS).

A content of the bis(trifluoromethyl)benzidine (TFDB) may be 70 to 80 mol %, with respect to a total mole number of the diamine monomer.

The diamine monomer may further include bis(4-aminophenyl)sulfone (4DDS).

A content of the bis(trifluoromethyl)benzidine (TFDB) may be 70 to 80 mol % and a total content of the bis(3-aminophenyl)sulfone (3DDS) and the bis(4-aminophenyl)sulfone (4DDS) may be 20 to 30 mol %, with respect to a total mole number of the diamine monomer.

The dianhydride compound may include at least one of 2,2-bis(3,4-dicarboxyphenyl) hexafluoropropane dianhydride (6FDA), biphenyltetracarboxylic dianhydride (BPDA), or 1,2,3,4-cyclobutanetetracarboxylic dianhydride (CBDA).

The dicarbonyl compound may include terephthaloyl chloride (TPC).

The polymerizable composition may contain the dianhydride compound and the dicarbonyl compound.

A molar ratio of the dianhydride compound to the dicarbonyl compound may be 50:50 to 2:98.

When a mole number of the dicarbonyl compound is 70% or less with respect to a total mole number of the dianhydride compound and the dicarbonyl compound, the dianhydride compound may include two or more types of dianhydride compounds.

A molar ratio of the dianhydride compound to the dicarbonyl compound may be 10:90 to 2:98.

In accordance with another aspect of the present disclosure, provided is a display device including a display panel and the optical film disposed on the display panel.

### Advantageous Effects

The optical film according to an embodiment of the present disclosure has excellent Shore D hardness and thus excellent surface stiffness.

The optical film according to an embodiment of the present disclosure has excellent tensile modulus and excellent mechanical properties.

The optical film according to an embodiment of the present disclosure has an excellent Stiff Index and thus exhibits both excellent surface properties and superior mechanical properties.

The optical film according to an embodiment of the present disclosure has excellent puncture strength and thus exhibits excellent mechanical properties.

The display device including an optical film according to an embodiment of the present disclosure has excellent display quality and maintains excellent display quality even when used for a long time.

### DESCRIPTION OF DRAWINGS

FIG. 1 is a cross-sectional view illustrating a part of a display device according to one embodiment of the present disclosure.

FIG. 2 is an enlarged cross-sectional view illustrating part “P” in FIG. 1.

FIG. 3 is a schematic cross-sectional view illustrating measurement of the Shore D hardness of the optical film according to an embodiment of the present disclosure.

### BEST MODE

Hereinafter, embodiments of the present disclosure will be described in detail with reference to the accompanying drawings. However, the following embodiments are illustratively provided merely for better understanding of the present disclosure and do not limit the scope of the present disclosure.

The shapes, sizes, ratios, angles, and numbers disclosed in the drawings for describing embodiments of the present disclosure are merely examples, and the present disclosure is not limited to the illustrated details. Like reference numerals refer to like elements throughout the present specification. In the following description, when a detailed description of relevant known functions or configurations is determined to unnecessarily obscure important points of the present disclosure, the detailed description will be omitted.

In the case in which a term such as “comprise”, “have”, or “include” is used in the present specification, another part may also be present, unless “only” is also used. Terms in a singular form may include the plural meanings, unless noted to the contrary. Also, in construing an element, the element is to be construed as including an error range, even if there is no explicit description thereof.

In describing a positional relationship, for example, when the positional relationship is described using “on”, “above”, “below”, or “next to”, the case of no contact therebetween may be included, unless “immediately” or “directly” is used.

Spatially relative terms, such as “below”, “beneath”, “lower”, “above”, and “upper”, may be used herein to describe the relationship between a device or element and another device or element, as shown in the figures. It will be understood that spatially relative terms are intended to encompass different orientations of a device during the use or operation of the device, in addition to the orientation depicted in the figures. For example, if a device in one of the figures is turned upside down, elements described as “below” or “beneath” other elements would then be positioned “above” the other elements. The exemplary term “below” or “beneath” can, therefore, encompass the meanings of both “below” and “above”. In the same manner, the exemplary term “above” or “upper” can encompass the meanings of both “above” and “below”.

In describing temporal relationships, for example, when a temporal order is described using “after”, “subsequent”, “next”, or “before”, the case of a non-continuous relationship may be included, unless “immediately” or “directly” is used.

It will be understood that, although the terms “first”, “second”, etc. may be used herein to describe various elements, these elements are not limited by these terms. These terms are only used to distinguish one element from another. Therefore, a first element could be termed a second element within the technical idea of the present disclosure.

It should be understood that the term “at least one” includes all combinations related with one or more items. For example, “at least one among a first element, a second element, and a third element” may include all combinations of two or more elements selected from among the first, second, and third elements, as well as each of the first, second, and third elements.

Features of various embodiments of the present disclosure may be partially or completely integrated or combined with each other.

The present disclosure may be modified in various ways and may have various embodiments. Hereinafter, specific embodiments will be described in detail based on the accompanying drawings.

One embodiment of the present disclosure provides an optical film 100.

The optical film 100 according to one embodiment may have a Shore D hardness of 15 to 19 HD, based on a thickness of 50 μm.

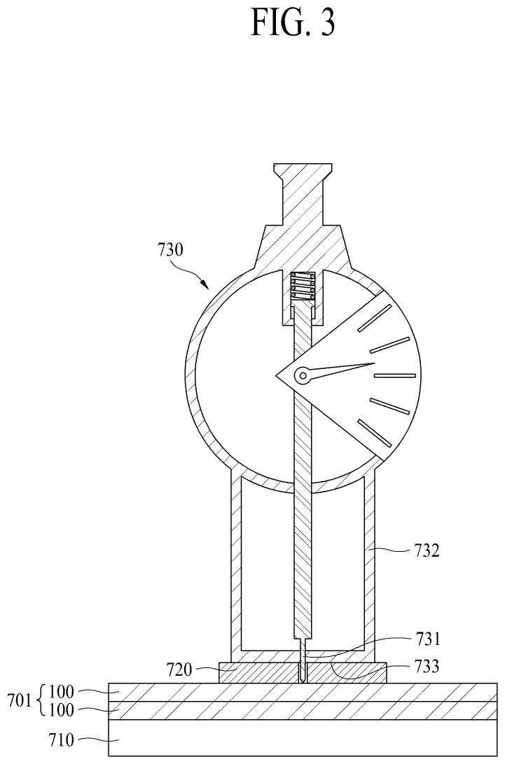

The Shore D hardness is used to evaluate the surface stiffness of the film and may be measured using a Shore D hardness meter 730 (see FIG. 3). For example, a Sauter's Shore D hardness meter is used as a Shore D hardness meter 730 and the indenter 731 of the Shore D hardness meter has a sharp conical shape with an angle of 30°. The unit of Shore D hardness may be defined as “HD”.

According to an embodiment of the present disclosure, a test block 720 may be used to measure the Shore D hardness of the optical film 100. The test block 720 may serve to fix the optical film 100 when measuring Shore D hardness. The test block 720 has a hole in the center and the sharp end of the indenter 731 of the Shore D hardness meter may be inserted into the hole to measure the Shore D hardness of the optical film 100 placed at the bottom of the test block 720.

The detailed method of measuring Shore D hardness will be described later.

When the Shore D hardness is less than 15 HD, the optical film 100 may be scratched by external force due to low surface stiffness thereof. When the Shore D hardness is greater than 19 HD, the optical film 100 may be readily cracked by external force due to surface stiffness thereof.

The optical film 100 according to an embodiment of the present disclosure may have a tensile modulus of 5.0 to 10.0 GPa based on a thickness of 50 μm.

The tensile modulus is used to evaluate the mechanical strength of the film and refers to an elastic modulus between stress and strain measured while the optical film 100 stretches. The tensile modulus may be measured using a universal testing machine (UTM). The universal testing machine (UTM) is, for example, INSTRON's universal testing machine (UTM). The unit of the tensile modulus is GPa.

When the tensile modulus is less than 5.0 GPa, the optical film 100 may be easily deformed or broken by external force. When the tensile modulus is greater than 10.0 GPa, the optical film 100 is not easily deformed by external force, but this may cause problems associated with application. For example, when the optical film 100 is applied to a flexible display device, the difference in drag between the optical film 100 and other materials increases, resulting in separation or folding between the optical film and other material layers when folding or rolling the flexible display device.

The optical film 100 according to an embodiment of the present disclosure may have a Stiff Index of 80 to 190 based on a thickness of 50 μm. Stiff Index may indicate the correlation between the surface characteristics of the optical film 100 and the tensile modulus.

Specifically, as the Shore D hardness increases, the hardness of the optical film 100 increases, and as the tensile modulus increases, the thickness stiffness of the optical film 100 increases. Therefore, the Stiff Index is a factor that can indicate both the surface stiffness and thickness stiffness of the optical film 100.

The Stiff Index is expressed in Equation 1 below. In Equation 1 below, “STI” means Stiff Index. The unit of Stiff Index may be defined as HD×GPa.

$$STI = Shore D hardness \times tensile modulus \qquad [ Equation 1 ]$$

wherein the Shore D hardness is measured using a Shore D hardness tester and the tensile modulus is measured using a universal testing machine.

When the Stiff Index is less than 80, the optical film 100 may become excessively soft and may be easily deformed by external force. When the Stiff Index exceeds 190, the optical film 100 may become excessively hard and may be easily broken by external force.

The optical film 100 according to an embodiment of the present disclosure may have a puncture strength of 0.30 N/μm or more.

The optical film 100 is fixed to the jig using a universal testing machine (UTM), the force at the moment when the probe descended and the optical film 100 was broken was measured, and a value obtained by dividing the measured force by the thickness was defined as “puncture strength”. For example, INSTRON's universal testing machine (UTM) may be used as the universal testing machine (UTM), INSTRON's S1-11855 may be used as a jig, and INSTRON's 2830-005 (1.59 mm×8 cm) may be used as a probe. The unit of puncture strength can be defined as “N/μm”.

When the puncture strength is less than 0.30 N/μm, the optical film 100 may be easily broken by external impact.

The optical film 100 according to an embodiment of the present disclosure includes a polymer resin.

The optical film 100 according to an embodiment of the present disclosure may include at least one of an imide repeating unit or an amide repeating unit. For example, the optical film 100 according to an embodiment of the present disclosure may include at least one of polyimide-based polymers, polyamide-based polymers, or polyamide-imide-based polymers.

The optical film 100 according to an embodiment of the present disclosure may include an imide repeating unit produced from a diamine-based compound and a dianhydride-based compound.

The optical film 100 according to an embodiment of the present disclosure may include both an imide repeating unit and an amide repeating unit produced from a diamine-based compound, a dicarbonyl-based compound and a dianhydride-based compound.

In the optical film 100 according to an embodiment of the present disclosure, the ratio of the imide repeating unit to the amide repeating unit may be 50:50 to 2:98 based on the number of repeating units.

More specifically, the ratio of the imide repeating unit to the amide repeating unit may be 10:90 to 2:98 based on the number of repeating units.

The optical film 100 according to an embodiment of the present disclosure may be produced from a polymerizable composition.

The optical film 100 according to an embodiment of the present disclosure may be manufactured from, for example, at least one of a polyimide polymerizable composition, a polyamide polymerizable composition, and a polyamide-imide polymerizable composition.

The optical film 100 according to an embodiment of the present disclosure may be any one of a polyimide-based film, a polyamide-based film, or a polyamide-imide-based film. However, the embodiment of the present disclosure is not limited thereto and any film having light transparency may be the optical film 100 according to an embodiment of the present disclosure.

The polymerizable composition according to an embodiment of the present disclosure may contain a diamine-based monomer.

According to an embodiment of the present disclosure, the diamine monomer may include, for example, bis(trifluoromethyl)benzidine (TFDB). For example, the diamine monomer according to an embodiment of the present disclosure may include bis(trifluoromethyl)benzidine (TFDB) and sulfone diamine. The sulfone-based diamine may include, for example, at least one of bis(3-aminophenyl)sulfone (3DDS) or bis(4-aminophenyl)sulfone (4DDS).

Specifically, according to one embodiment of the present disclosure, the diamine monomer may further include, for example, bis(3-aminophenyl)sulfone (3DDS).

Bis(trifluoromethyl)benzidine (TFDB) imparts mechanical properties to the optical film 100. However, for example, the optical film 100 requires flexibility in order for the optical film 100 to be applied to a flexible display device. Therefore, bis(3-aminophenyl)sulfone (3DDS) may be used as the diamine monomer to impart appropriate flexibility to the optical film 100.

When the diamine monomer further includes bis(3-aminophenyl)sulfone (3DDS), the content of bis(trifluoromethyl)benzidine (TFDB) may be 70 to 80 mol % and the content of bis(3-aminophenyl)sulfone (3DDS) may be 20 to 30 mol %, based on the total mole number of diamine monomers.

When the content of bis(trifluoromethyl)benzidine (TFDB) is less than 70 mol %, the yellowness of the optical film 100 may increase, and heat resistance and mechanical properties may be insufficient. When the content of bis(trifluoromethyl)benzidine (TFDB) is higher than 80 mol %, the flexibility of the optical film 100 may be insufficient.

According to an embodiment of the present disclosure, the diamine monomer may further include, for example, bis(4-aminophenyl)sulfone (4DDS).

The bis(4-aminophenyl)sulfone (4DDS) inhibits the packing of polymer chains, thereby improving the optical properties of the optical film 100. However, when the bis(4-aminophenyl)sulfone (4DDS) is present in an excess, the mechanical properties of the optical film 100 may be reduced. Therefore, when polymerization is performed while the content of bis(4-aminophenyl)sulfone (4DDS) is controlled within an appropriate range, the mechanical properties and optical properties of the optical film 100 can be improved in a balanced manner.

When the diamine monomer further includes bis(4-aminophenyl)sulfone (4DDS), the content of bis(trifluoromethyl)benzidine (TFDB) may be 70 to 80 mol %, and the total content of bis(3-aminophenyl)sulfone (3DDS) and bis(4-aminophenyl)sulfone (4DDS) may be 20 to 30 mol %, based on the total mole number of the diamine monomer.

The polymerizable composition according to an embodiment of the present disclosure may contain at least one of a dianhydride compound or a dicarbonyl compound.

For example, the polymerizable composition according to an embodiment of the present disclosure may contain a dianhydride compound and a dicarbonyl compound.

According to an embodiment of the present disclosure, the molar ratio of the dianhydride compound to the dicarbonyl compound of the polymerizable composition may range from 50:50 to 2:98.

More specifically, the molar ratio of the dianhydride compound to the dicarbonyl compound in the polymerizable composition may range from 10:90 to 2:98.

However, according to one embodiment of the present disclosure, when the mole number of the dicarbonyl compound is 70% or less with respect to the total mole number of the dianhydride compound and the dicarbonyl compound of the polymerizable composition, the dianhydride compound may be used in a combination of two or more types.

More specifically, for example, when the content of terephthaloyl chloride (TPC), which is a dicarbonyl compound in the polymerizable composition according to an embodiment of the present disclosure, is reduced to 70% or less, the stiffness of the optical film 100 may decrease. Therefore, two or more types of dianhydride compounds may be used to compensate for the reduced stiffness.

According to an embodiment of the present disclosure, the total equivalent weight of the dianhydride compound and the dicarbonyl compound may be substantially equal to the equivalent weight of the diamine monomer.

The dianhydride compound may include at least one of 2,2-bis(3,4-dicarboxyphenyl)hexafluoropropane dianhydride (6FDA), biphenyltetracarboxylic dianhydride (BPDA), or 1,2,3,4-cyclobutanetetracarboxylic dianhydride (CBDA).

According to an embodiment of the present disclosure, Stiff Index is a parameter indicating the surface stiffness and thickness stiffness of the optical film 100. As the molecular chain length of the component constituting the polymer structure of the optical film 100 decreases or the functional groups thereof are aligned in a straight line, the Stiff Index of the optical film 100 is better. Therefore, it is preferable to use a dianhydride compound having a small molecular size.

In this respect, for example, 1,2,3,4-cyclobutanetetracarboxylic dianhydride (CBDA) may be used. More specifically, when TPC is used as the dicarbonyl compound, the stiffness of the optical film 100 according to an embodiment of the present disclosure can be improved by using TPC in combination with a predetermined amount of 1,2,3,4-cyclobutanetetracarboxylic dianhydride (CBDA). According to an embodiment of the present disclosure, in consideration of stiffness improvement and manufacturing process ability, 1,2,3,4-cyclobutanetetracarboxylic dianhydride (CBDA) may be used in an amount of 20 to 40 mol %, with respect to the total mole number of the dianhydride compound and the dicarbonyl compound.

According to an embodiment of the present disclosure, 1,2,3,4-cyclobutanetetracarboxylic dianhydride (CBDA) may be used in combination with 2,2-bis(3,4-dicarboxyphenyl)hexafluoropropane dianhydride (6FDA). For example, the polymerizable composition according to an embodiment of the present disclosure includes dianhydride compounds such as 1,2,3,4-cyclobutanetetracarboxylic dianhydride (CBDA) and 2,2-bis(3,4-dicarboxyphenyl)hexafluoropropane dianhydride (6FDA).

When the polymerizable composition contains, as dianhydride compounds, 1,2,3,4-cyclobutanetetracarboxylic dianhydride (CBDA) and 2,2-bis(3,4-dicarboxyphenyl)hexafluoropropane dianhydride (6FDA), it may contain 10 to 15 mol % of the 2,2-bis(3,4-dicarboxyphenyl)hexafluoropropane dianhydride (6FDA) and 25 to 35 mol % of the 1,2,3,4-cyclobutanetetracarboxylic dianhydride (CBDA), with respect to the total mole number of the dianhydride compound and the dicarbonyl compound.

According to an embodiment of the present disclosure, 2,2-bis(3,4-dicarboxyphenyl)hexafluoropropane dianhydride (6FDA) may be used in an amount of 15 mol % or less with respect to the total mole number of the dianhydride compound and the dicarbonyl compound. In this case, as the dianhydride compound, 1,2,3,4-cyclobutanetetracarboxylic dianhydride (CBDA) may be used in combination with 2,2-bis(3,4-dicarboxyphenyl)hexafluoropropane dianhydride (6FDA).

The polymerizable composition according to an embodiment of the present disclosure contains 50 to 65 mol % of the dicarbonyl compound, 25 to 35 mol % of 1,2,3,4-cyclobutanetetracarboxylic dianhydride (CBDA), and 10 to 15 mol % of 2,2-bis(3,4-dicarboxyphenyl)hexafluoropropane dianhydride (6FDA), based on the total mole number of the dianhydride compound and the dicarbonyl compound.

According to an embodiment of the present disclosure, the dicarbonyl compound has a benzene ring and can exhibit high thermal stability and mechanical properties, but this causes high birefringence. However, when bis(trifluoromethyl)benzidine (TFDB) is used as the diamine monomer, thermal stability and optical properties can be improved. In addition, when polymerization is performed while controlling the contents of the dianhydride compound, the dicarbonyl compound, and the diamine monomer within appropriate ranges, the thermal stability, mechanical properties, and optical properties of the optical film 100 can be improved in a balanced manner.

According to an embodiment of the present disclosure, the dicarbonyl compound of the polymerizable composition may include terephthaloyl chloride (TPC).

In addition, the polymerizable composition according to an embodiment of the present disclosure may contain a diamine monomer and a dicarbonyl compound. For example, the polymerizable composition may be prepared from the diamine monomer and the dicarbonyl compound without a dianhydride compound.

When the polymerizable composition is prepared from the diamine monomer and the dicarbonyl compound, for example, the diamine monomer may include bis(trifluoromethyl)benzidine (TFDB) and a sulfone-based diamine. The sulfone-based diamine may include at least one of bis(3-aminophenyl)sulfone (3DDS) or bis(4-aminophenyl)sulfone (4DDS). More specifically, according to one embodiment of the present disclosure, the diamine monomer may include bis(trifluoromethyl)benzidine (TFDB) and bis(3-aminophenyl)sulfone (3DDS).

In addition, when the polymerizable composition is prepared from a diamine monomer and a dicarbonyl compound, for example, the diamine monomer may contain 70 to 80 mol % of bis(trifluoromethyl)benzidine (TFDB) and 20 to 30 mol % of sulfone-based diamine.

The optical film 100 according to an embodiment of the present disclosure may include an amide repeating unit produced from a diamine-based compound and a dicarbonyl-based compound.

According to an embodiment of the present disclosure, a polyamide film manufactured from a polymerizable composition containing a diamine monomer including bis(trifluoromethyl)benzidine (TFDB) and bis(3-aminophenyl)sulfone (3DDS), and a dicarbonyl compound, without a dianhydride compound, may have an excellent Stiff Index.

Hereinafter, a method of producing the optical film 100 according to an embodiment of the present disclosure will be described.

Here, the polymerizable composition according to an embodiment of the present disclosure is also referred to as a polymer resin solution.

The method of producing the optical film 100 according to an embodiment of the present disclosure includes forming a first reaction solution using a diamine monomer and a dianhydride compound, adding a dicarbonyl compound to the first reaction solution and allowing a reaction to occur therebetween to form a second reaction solution, adding a dehydrating agent and an imidization catalyst to the first reaction solution and allowing a reaction to occur therebetween to form a second reaction solution, adding a dehydrating agent and an imidization catalyst to the second reaction solution and allowing a reaction to occur therebetween to form a third reaction solution, treating the third reaction solution to prepare a polymer resin in a solid phase, dissolving the solid-phase polymer resin to prepare a polymer resin solution, and casting the polymer resin solution. Hereinafter, each step will be described in detail.

First, a first reaction solution is formed using a diamine monomer and a dianhydride compound.

The solvent for preparing the first reaction solution may be, for example, a polar aprotic organic solvent such as N,N-dimethylacetamide (DMAc), N,N-dimethylformamide (DMF), 1-methyl-2-pyrrolidinone (NMP), m-cresol, tetrahydrofuran (THF), chloroform, methyl ethyl ketone (MEK), or a mixture thereof. However, the solvent according to an embodiment of the present disclosure is not limited thereto and other solvents may be used.

The diamine monomer may include bis(trifluoromethyl)benzidine (TFDB) and may further include bis(3-aminophenyl)sulfone (3DDS). In addition, the diamine monomer may further include bis(4-aminophenyl) sulfone (4DDS).

However, the diamine monomer according to an embodiment of the present disclosure is not limited thereto and other diamine monomers may be used.

When the diamine monomer further includes bis(3-aminophenyl)sulfone (3DDS) in addition to bis(trifluoromethyl)benzidine (TFDB), the content of bis(trifluoromethyl)benzidine (TFDB) may be 70 to 80 mol %, and the content of bis(3-aminophenyl)sulfone (3DDS) may be 20 to 30 mol %.

When the diamine monomer further includes bis(4-aminophenyl)sulfone (4DDS) in addition to bis(trifluoromethyl)benzidine (TFDB) and bis(3-aminophenyl)sulfone (3DDS), the sum of the contents of bis(3-aminophenyl)sulfone (3DDS) and bis(4-aminophenyl)sulfone (4DDS) may be 20 to 30 mol %.

The dianhydride compound includes at least one of 2,2-bis(3,4-dicarboxyphenyl)hexafluoropropane dianhydride (6FDA), biphenyltetracarboxylic dianhydride (BPDA), or 1,2,3,4-cyclobutanetetracarboxylic dianhydride (CBDA).

However, the dianhydride compound according to an embodiment of the present disclosure is not limited thereto and other dianhydride compounds may be used.

According to an embodiment of the present disclosure, the first reaction solution may contain polyamic acid and a polyamide repeating unit.

Next, a dicarbonyl compound is added to the first reaction solution and allows a reaction to occur therebetween to form a second reaction solution. For example, a dicarbonyl compound may be added to the first reaction solution 1 to 24 hours after formation of the first reaction solution. More specifically, a dicarbonyl compound may be added to the first reaction solution 1 to 20 hours after formation of the first reaction solution.

According to an embodiment of the present disclosure, when the dicarbonyl compound begins to be added to the first reaction solution, the resulting reaction solution is called “the second reaction solution”.

The dicarbonyl compound may include terephthaloyl chloride (TPC).

However, the dicarbonyl compound according to an embodiment of the present disclosure is not limited thereto and other dicarbonyl compounds may be used.

According to an embodiment of the present disclosure, the molar ratio of the dianhydride compound to the dicarbonyl compound may range from 50:50 to 2:98.

More specifically, the molar ratio of the dianhydride compound to the dicarbonyl compound may range from 10:90 to 2:98.

However, according to one embodiment of the present disclosure, when the mole number of the dicarbonyl compound is 70% or less with respect to the total mole number of the dianhydride compound and the dicarbonyl compound, the dianhydride compound may include at least two types of dianhydride compounds.

Next, a dehydrating agent and an imidization catalyst are added to the second reaction solution and allow a reaction to occur therebetween to form a third reaction solution.

According to an embodiment of the present disclosure, the dehydrating agent and imidization catalyst are added to the second reaction solution, followed by flux stirring at a temperature of 60 to 80° C. for 30 minutes to 2 hours. As a result, a third reaction solution may be formed.

The dehydrating agent may be an acid anhydride such as acetic anhydride, propionic anhydride, isobutyric anhydride, pivalic anhydride, butyric anhydride, or isovaleric anhydride.

The imidization catalyst may be a tertiary amine such as isoquinoline, beta-picoline, or pyridine.

Next, the third reaction solution is treated to prepare a polymer resin in a solid phase.

In order to prepare the solid-phase polymer resin, a solvent may be added to the third reaction solution. The solvent may, for example, be ethanol, methanol, hexane, or the like. The solvent may be used alone or in a mixture of two or more solvents.

When a solvent that has low polarity and is miscible with the polymerization solvent is added to the third reaction solution, a solid polymer resin in a powder phase is precipitated. By filtering and drying the precipitate, a highly pure solid polymer resin can be obtained. When liquid components are removed in the process of filtering the precipitate, unreacted monomers, oligomers, additives, and reaction byproducts are removed.

The polymer resin thus obtained may be a solid powder and may include an imide repeating unit and an amide repeating unit. The polymer resin may be, for example, a polyamide-imide-based resin.

Next, the solid-phase polymer resin is dissolved to prepare a polymer resin solution. A step of preparing the polymer resin solution by dissolving the solid-phase polymer resin in a solvent is called “re-dissolution”.

The solvent used to dissolve the solid-phase polymer resin may be the same as any of those used in the polymerization. The solvent that can be used to dissolve the solid-phase polymer resin may, for example, be a polar aprotic organic solvent such as N,N-dimethylacetamide (DMAc), N,N-dimethylformamide (DMF), 1-methyl-2-pyrrolidinone (NMP), m-cresol, tetrahydrofuran (THF), chloroform, methyl ethyl ketone (MEK), or a mixture thereof. However, the solvent according to the present disclosure is not limited thereto, and other well-known solvents may also be used.

Next, the polymer resin solution is cast.

A casting substrate is used for casting. There is no particular limitation as to the type of casting substrate. The casting substrate may be a glass substrate, an aluminum substrate, a stainless steel (SUS) substrate, a Teflon substrate, or the like. According to an embodiment of the present disclosure, the casting substrate may be, for example, a glass substrate.

Specifically, casting is achieved by applying the polymer resin solution to the casting substrate. A coater, a blade, or the like may be used for casting. According to an embodiment of the present disclosure, for example, a Baker film applicator may be used for casting.

After casting, the polymer resin solution is dried while the temperature is elevated to 80 to 120° C. at a rate of 2° C./min to produce a coating film of the polymer resin. The coating film thus produced may be referred to as an “intermediate of the optical film”. After the coating film is pulled taut to a pin-type tenter and fixed thereto, heat treatment is performed at a constant temperature of 270° C. for 10 minutes. As a result, an optical film 100 can be manufactured.

The optical film 100 according to an embodiment of the present disclosure can be applied to a display device to protect the display surface of the display panel. The optical film 100 according to an embodiment of the present disclosure may have a thickness sufficient to protect the display panel. For example, the optical film 100 may have a thickness of 10 to 100 μm.

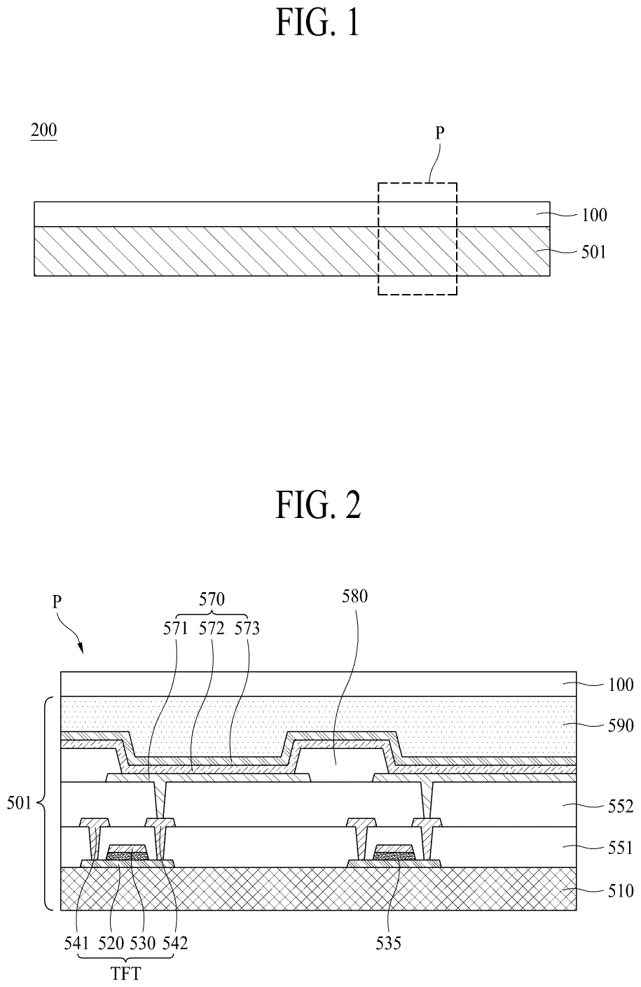

Hereinafter, a display device using the optical film 100 according to an embodiment of the present disclosure will be described with reference to FIGS. 1 and 2.

FIG. 1 is a cross-sectional view illustrating a part of a display device 200 according to another embodiment, and FIG. 2 is an enlarged cross-sectional view of “P” in FIG. 1.

Referring to FIG. 1, the display device 200 according to another embodiment of the present disclosure includes a display panel 501 and an optical film 100 on the display panel 501.

Referring to FIGS. 1 and 2, the display panel 501 includes a substrate 510, a thin film transistor TFT on the substrate 510, and an organic light-emitting device 570 connected to the thin film transistor TFT. The organic light-emitting device 570 includes a first electrode 571, an organic light-emitting layer 572 on the first electrode 571, and a second electrode 573 on the organic light-emitting layer 572. The display device 200 shown in FIGS. 1 and 2 is, for example, an organic light-emitting display device.

The substrate 510 may be formed of glass or plastic. Specifically, the substrate 510 may be formed of plastic such as a polyimide-based resin. Although not shown, a buffer layer may be disposed on the substrate 510.

The thin film transistor TFT is disposed on the substrate 510. The thin film transistor TFT includes a semiconductor layer 520, a gate electrode 530 that is insulated from the semiconductor layer 520 and at least partially overlaps the semiconductor layer 520, a source electrode 541 connected to the semiconductor layer 520, and a drain electrode 542 that is spaced apart from the source electrode 541 and is connected to the semiconductor layer 520.

Referring to FIG. 3, a gate insulating layer 535 is disposed between the gate electrode 530 and the semiconductor layer 520. An interlayer insulating layer 551 may be disposed on the gate electrode 530 and the source electrode 541 and the drain electrode 542 may be disposed on the interlayer insulating layer 551.

A planarization layer 552 is disposed on the thin film transistor TFT to planarize the top of the thin film transistor TFT.

A first electrode 571 is disposed on the planarization layer 552. The first electrode 571 is connected to the thin film transistor TFT through a contact hole provided in the planarization layer 552.

A bank layer 580 is disposed on the planarization layer 552 in a part of the first electrode 571 to define pixel areas or light-emitting areas. For example, the bank layer 580 is disposed in the form of a matrix at the boundaries between a plurality of pixels to define the respective pixel regions.

The organic light-emitting layer 572 is disposed on the first electrode 571. The organic light-emitting layer 572 may also be disposed on the bank layer 580. The organic light-emitting layer 572 may include one light-emitting layer, or two or more light-emitting layers stacked in a vertical direction. Light having any one color among red, green, and blue may be emitted from the organic light-emitting layer 572, and white light may be emitted therefrom.

The second electrode 573 is disposed on the organic light-emitting layer 572.

The first electrode 571, the organic light-emitting layer 572, and the second electrode 573 may be stacked to constitute the organic light-emitting device 570.

Although not shown, when the organic light-emitting layer 572 emits white light, each pixel may include a color filter for filtering the white light emitted from the organic light-emitting layer 572 based on a particular wavelength. The color filter is formed in the light path.

A thin-film encapsulation layer 590 may be disposed on the second electrode 573. The thin-film encapsulation layer 590 may include at least one organic layer and at least one inorganic layer, and the at least one organic layer and the at least one inorganic layer may be alternately disposed.

The optical film 100 is disposed on the display panel 501 having the stack structure described above.

Hereinafter, the present disclosure will be described in more detail with reference to Examples and Comparative Examples. However, the following Examples and Comparative Examples are provided only for better understanding of the present disclosure and should not be construed as limiting the scope of the present disclosure.

### EXAMPLE 1

313.34 g of N,N-dimethylacetamide (DMAc) was charged in a 500 mL reactor equipped with a stirrer, a nitrogen injector, a dropping funnel, a temperature controller, and a cooler while nitrogen was passed through the reactor. Then, 24.02 g (0.075 mol) of 2,2′-bis(trifluoromethyl)-4,4′-diaminobiphenyl (2,2′-TFDB), as an aromatic diamine, was slowly added and then dissolved therein. Then, 6.21 g (0.025 mol) of bis(3-aminophenyl)sulfone (3DDS) was further added and dissolved therein.

The diamine was dissolved and then 0.89 g (0.002 mol) of 2,2-bis(3,4-dicarboxyphenyl)hexafluoropropane dianhydride (6FDA), as a dianhydride compound, was added thereto, followed by stirring for 2 hours. [Formation of first reaction solution]

Then, 19.90 g (0.098 mol) of terephthaloyl chloride (TPC), as a dicarbonyl compound, was added at 10° C. or lower, followed by allowing reaction for 1 hour [Formation of second reaction solution].

After the polymerization reaction was completed, the temperature of the second reaction solution was raised to room temperature, and then 0.35 g of pyridine and 0.45 g of acetic anhydride were added in an amount corresponding to 2.2 times the number of moles of the dianhydride compound added, followed by stirring at 80° C. for 30 minutes.

### [Formation of Third Reaction Solution]

The flask was cooled to room temperature and excess methanol was added dropwise to the third reaction solution to cause precipitation. The precipitate was filtered and dried using a pressure reduction filter to obtain a polymer resin as a white solid. The obtained polymer resin is in a solid powder phase.

The polymer resin in the form of solid powder thus obtained was re-dissolved in N,N′-dimethylacetamide (DMAc) to obtain a polymer resin solution having a solid concentration of 14% by weight.

The polymer resin solution was cast on a glass plate. Specifically, the polymer resin solution was applied to a glass plate using a Baker film applicator and primarily dried at 80° C. for 20 minutes with hot air and at 120° C. for 20 minutes to form a coating film.

After the primary drying, the film was peeled off the glass plate and fixed to a pin frame. The result was secondarily dried with a hot air at a constant temperature of 270° C. to obtain an optical film having a thickness of 50 μm.

### Examples 2 to 8

Optical films according to Examples 2 to 8 were manufactured under the conditions in the following Table 1 in the same manner as in Example 1.

### Comparative Examples 1 to 5

Optical films according to Comparative Examples 1 to 5 were manufactured under the conditions in the following Table 1 in the same manner as in Example 1.

TABLE 1

| | Diamine monomer (mol %) | | | | | | Dianhydride compound (mol %) | | | | Dicarbonyl compound | |
|---|---|---|---|---|---|---|---|---|---|---|---|---|
| Type | TFDB | | 3DDS | | 4DDS | FFDA | CBDA | 6FDA | | BPDA | (mol %) TPC | |
| Example 1 | 75 | mol % | 25 | mol % | — | — | — | 2 | mol % | — | 98 | mol % |

| | | | | | | | | | | | | |
|---|---|---|---|---|---|---|---|---|---|---|---|---|
| Example 2 | 75 | mol % | 25 | mol % | — | — | — | — | 5 | mol % | 95 | mol % |

| | | | | | | | | | | | | | |
|---|---|---|---|---|---|---|---|---|---|---|---|---|---|
| Example 3 | 75 | mol % | 20 | mol % | 5 | mol % | — | — | 2 | mol % | — | 98 | mol % |

| | | | | | | | | | | | |
|---|---|---|---|---|---|---|---|---|---|---|---|
| Example 4 | 100 | mol % | — | — | — | 26 mol % | 13 | mol % | — | 61 | mol % |
| Example 5 | 100 | mol % | — | — | — | 29 mol % | 10 | mol % | — | 61 | mol % |
| Example 6 | 100 | mol % | — | — | — | 35 mol % | 11 | mol % | — | 54 | mol % |

| | | | | | | | | | | | |
|---|---|---|---|---|---|---|---|---|---|---|---|
| Example 7 | 75 | mol % | 25 | mol % | — | — | — | — | — | 100 | mol % |
| Example 8 | 73 | mol % | 27 | mol % | — | — | — | — | — | 100 | mol % |

| | | | | | | | | | | | |
|---|---|---|---|---|---|---|---|---|---|---|---|
| Comparative Example 1 | 60 | mol % | — | 40 | mol % | — | — | — | — | 100 | mol % |
| Comparative Example 2 | 40 | mol % | — | 60 | mol % | — | — | — | — | 100 | mol % |

| | | | | | | | | | | |
|---|---|---|---|---|---|---|---|---|---|---|
| Comparative Example 3 | — | — | — | 100 mol % | — | — | 25 | mol % | 75 | mol % |

| | | | | | | | | | | | |
|---|---|---|---|---|---|---|---|---|---|---|---|
| Comparative Example 4 | 100 | mol % | — | — | — | — | 45 | mol % | — | 55 | mol % |
| Comparative Example 5 | 100 | mol % | — | — | — | — | 60 | mol % | — | 40 | mol % |

The physical properties of the optical films manufactured in Examples 1 to 8 and Comparative Examples 1 to 5 were measured as follows.

### (1) Measurement of Shore D Hardness

1) FIG. 3 is a schematic cross-sectional view illustrating measurement of Shore D hardness using the Shore D hardness tester 730.

According to an embodiment of the present disclosure, for example, the Shore D hardness of the optical film 100 may be measured using the Shore D hardness meter 730 shown in FIG. 3.

According to an embodiment of the present disclosure, a test block 720 may be used to measure the Shore D hardness of the optical film 100. The test block 720 may serve to fix the optical film 100 when measuring Shore D hardness. The test block 720 has a hole in the center and the sharp tip of an indenter 731 of the Shore D hardness meter may be inserted into the hole to measure the Shore D hardness of the optical film 100 placed at the bottom of the test block 720.

### 2) Details of Measurement Method

A laminate of the two optical films with a total thickness of 100 μm (each optical film having a thickness of 50 μm) manufactured according to Examples 1 to 8 and Comparative Examples 1 to 5 was placed on Parafilm 710 with a thickness of 500 μm, a test block 720 was placed on the optical film laminate 701, and the Shore D hardness of the optical film was measured using SAUTER's Shore D hardness tester 730. A force was applied at a height of 1 cm from the surface of the optical film laminate 701, until the bottom 733 of an indenter support 732 completely contacted the test block 720, and Shore D hardness was measured 5 times. Then, an average of the values obtained by subtracting the minimum from the maximum three times was defined as a Shore D hardness. The unit of Shore D hardness is HD.

### (2) Measurement of Tensile Modulus

Specimens of the optical films manufactured according to Examples 1 to 8 and Comparative Examples 1 to 5 were prepared and the tensile modulus thereof was measured using a universal testing machine (UTM, Instron). The optical film specimen produced herein had a size of 10 mm (width)×50 mm (length). The tensile modulus of the optical film specimen was measured 3 to 5 times at a speed of 25 mm/min and an average of the measured values was calculated. The average was defined as a “tensile modulus”. The unit of tensile modulus is GPa.

### (3) Calculation of Stiff Index

Stiff index was calculated in accordance with Equation 1 using the measured Shore D hardness and tensile modulus. “STI” in Equation 1 below represents a Stiff Index. The unit of Stiff Index is HD×GPa.

$$STI = Shore D hardness \times tensile modulus \qquad [ Equation 1 ]$$

The results of calculation are shown in Table 2 below.

### (4) Measurement of Puncture Strength (Puncture Test)

An optical film specimen having a width of 6 cm was prepared, the force at which the probe dropped at a rate of 1,000 mm/min and burst the specimen was measured using a universal testing machine (UTM, Instron), a jig (S1-11855, Instron), and a probe (2830-005, Instron) with a size of 1.59 mm×8 cm, and the measured result was divided by the thickness. The resulting value was defined as “puncture strength”. The unit of puncture strength is N/μm.

TABLE 2

| | Shore D | Tensile | Stiff Index | Puncture |
|---|---|---|---|---|
| | hardness | modulus | (STI) | strength |
| Item | (HD) | (GPa) | (HD × GPa) | (N/μm) |
| Example 1 | 15.7 | 6.41 | 101 | O.33 |
| Example 2 | 15.3 | 6.03 | 92 | O.32 |
| Example 3 | 15.3 | 6.18 | 95 | O.31 |
| Example 4 | 16.0 | 6.46 | 103 | O.33 |
| Example 5 | 16.2 | 6.48 | 105 | 0.34 |
| Example 6 | 16.3 | 6.54 | 107 | 0.34 |
| Example 7 | 15.4 | 6.36 | 98 | 0.32 |
| Example 8 | 15.3 | 6.19 | 95 | 0.32 |
| Comparative | 14.8 | 4.77 | 71 | 0.25 |
| Example 1 | | | | |
| Comparative | 14.0 | 4.18 | 59 | 0.23 |
| Example 2 | | | | |
| Comparative | 14.3 | 3.73 | 65 | 0.28 |
| Example 3 | | | | |
| Comparative | 14.5 | 4.55 | 54 | 0.26 |
| Example 4 | | | | |
| Comparative | 14.2 | 4.37 | 51 | 0.23 |
| Example 5 | | | | |

As can be seen from the results of measurement in Table 2, the optical films of Examples 1 to 8 according to the present disclosure have Shore D hardness of 15 to 19 HD, based on a thickness of 50 μm. In addition, the optical films of Examples 1 to 8 according to the present disclosure have tensile modulus of 5.0 to 10.0 GPa based on a thickness of 50 μm.

The optical film according to embodiments of the present disclosure has a Stiff Index of 80 or more, and as a result, has excellent mechanical properties.

In addition, it can be seen that the optical films according to an embodiment of the present disclosure having a Stiff Index of 80 or more have a puncture strength of 0.30 N/μm or more.

As such, it can be seen that the optical films according to an embodiment of the present disclosure has excellent surface stiffness, excellent tensile strength, and excellent puncture strength.

Although the preferred embodiments of the present disclosure have been disclosed for illustrative purposes, those skilled in the art will appreciate that various modifications, additions and substitutions are possible, without departing from the scope and spirit of the disclosure as disclosed in the accompanying claims. The embodiments disclosed herein are provided only for illustrative purposes and should not be construed as limiting the scope of the present disclosure. Therefore, the substantial scope of the present disclosure should be defined by the claims and all technical ideas within equivalents to the claims should be construed as falling within the scope of the present disclosure.

### EXPLANATION OF REFERENCE NUMERALS

100: Optical film
200: Display device
501: Display panel
701: Optical film laminate
710: Parafilm
720: Test block
730: Shore D hardness tester
731: Indenter
732: Indenter support
733: Bottom of indenter support

1. An optical film having a Stiff Index of 80 to 190, based on a thickness of 50 μm,
wherein the Stiff Index is calculated by the following Equation 1:
$$STI = Shore D hardness \times tensile modulus \qquad [ Equation 1 ]$$
wherein STI represents a Stiff Index,
the Shore D hardness is measured using a Shore D hardness meter, and
the tensile modulus is measured using a universal testing machine.

2. The optical film according to claim 1, wherein the optical film has a Shore D hardness of 15 to 19 HD, based on a thickness of 50 μm.

3. The optical film according to claim 1, wherein the optical film has a tensile modulus of 5.0 to 10.0 GPa based on a thickness of 50 μm.

4. The optical film according to claim 1, wherein the optical film has a puncture strength of 0.30 N/μm or more.

5. The optical film according to claim 1, wherein the optical film comprises at least one of an imide repeating unit or an amide repeating unit.

6. The optical film according to claim 5, wherein the optical film comprises the imide repeating unit and the amide repeating unit,
wherein a ratio of the imide repeating unit to the amide repeating unit is 50:50 to 2:98, based on a total number of repeating units.

7. The optical film according to claim 6, wherein the optical film comprises the imide repeating unit and the amide repeating unit,
wherein a ratio of the imide repeating unit to the amide repeating unit is 10:90 to 2:98, based on the total number of repeating units.

8. The optical film according to claim 1, wherein the optical film is produced from a polymerizable composition comprising:
a diamine monomer; and
at least one of a dianhydride compound or a dicarbonyl compound.

9. The optical film according to claim 8, wherein the diamine monomer comprises bis(trifluoromethyl)benzidine (TFDB).

10. The optical film according to claim 9, wherein the diamine monomer further comprises bis(3-aminophenyl)sulfone (3DDS).

11. The optical film according to claim 10, wherein a content of the bis(trifluoromethyl)benzidine (TFDB) is 70 to 80 mol %, with respect to a total mole number of the diamine monomer.

12. The optical film according to claim 11, wherein the diamine monomer further comprises bis(4-aminophenyl)sulfone (4DDS).

13. The optical film according to claim 12, wherein a content of the bis(trifluoromethyl)benzidine (TFDB) is 70 to 80 mol %, and
a total content of the bis(3-aminophenyl)sulfone (3DDS) and the bis(4-aminophenyl)sulfone (4DDS) is 20 to 30 mol %, with respect to a total mole number of the diamine monomer.

14. The optical film according to claim 8, wherein
the dianhydride compound comprises at least one of 2,2-bis(3,4-dicarboxyphenyl) hexafluoropropane dianhydride (6FDA), biphenyltetracarboxylic dianhydride (BPDA), or 1,2,3,4-cyclobutanetetracarboxylic dianhydride (CBDA).

15. The optical film according to claim 8, wherein the dicarbonyl compound comprises terephthaloyl chloride (TPC).

16. The optical film according to claim 8, wherein the polymerizable composition comprises the dianhydride compound and the dicarbonyl compound.

17. The optical film according to claim 16, wherein a molar ratio of the dianhydride compound to the dicarbonyl compound is 50:50 to 2:98.

18. The optical film according to claim 17, wherein, when a mole number of the dicarbonyl compound is 70% or less with respect to a total mole number of the dianhydride compound and the dicarbonyl compound, the dianhydride compound includes two or more types of dianhydride compounds.

19. The optical film according to claim 17, wherein a molar ratio of the dianhydride compound to the dicarbonyl compound is 10:90 to 2:98.

20. A display device comprising:
a display panel; and
the optical film according to claim 1 disposed on the display panel.
